(19) United States
(12) Patent Application Publication
(10) Pub. No.: US 2025/0208233 A1
(43) Pub. Date: Jun. 26, 2025

(54) QUALITY DETECTION FOR MAGNETICALLY COUPLED INTERFACES

(71) Applicant: Microsoft Technology Licensing, LLC, Redmond, WA (US)

(72) Inventors: Donghwi KIM, Kirkland, WA (US); Jaejin LEE, Duvall, WA (US); Yonatan Moges BEYENE, Redmond, WA (US)

(21) Appl. No.: 18/392,592

(22) Filed: Dec. 21, 2023

(51) Int. Cl. G01R 31/66; G01D 5/14

(52) U.S. Cl. CPC G01R 31/66; G01D 5/145

(57) ABSTRACT

Techniques, software, and systems for enhanced notification of connector coupling quality between a connector and a user device are included. In one implementation a method includes obtaining indications of magnetic coupling properties of a connector with respect to a device. Based on at least the indications of the magnetic coupling properties, the method includes determining a coupling quality of a connection between the connector and the device. The method also includes providing an indication based at least on the coupling quality of the connection falling below a threshold quality level.

### BACKGROUND

In electronic devices, such as portable computing devices, various types of external power supply units can provide power to a device and charge batteries of the device. These power supply units often include a connector that couples to a receptacle or port of the device by a mechanical coupling. Power can be transferred by the power supply unit to the device via a power cable and connector. This arrangement might conform to a connection standard, such as Universal Serial Bus (USB) types of connections, including the USB Type C set of standards. Also, some connections can carry both power for a device as well as communication or data signaling. Connectors often rely on mechanical fitment or friction-based linkages to ensure electrical connections have been made.

Magnetic coupling has also been employed on some device connections, such as for laptop computer power connections or laptop power with communications. Magnetically-coupled connectors have become popular due to the user experience of improved safety and cable-trap avoidance. Problematically, magnetically-coupled charging cables and associated connectors commonly attract dust and other particles, which may cover or obstruct electrical contacts of the connector, or prevent proper connection and fitment.

### SUMMARY

Various examples discussed herein relate to monitoring connector coupling status and connection quality between a cable connector and a device. In one implementation, a method includes obtaining indications of magnetic coupling properties of a connector with respect to a device. Based on at least the indications of the magnetic coupling properties, the method includes determining a coupling quality of a connection between the connector and the device. The method also includes providing an indication based at least on the coupling quality of the connection falling below a threshold quality level.

In another example implementation, an apparatus including sensing circuitry and processing circuitry coupled to the sensing circuitry is provided. The sensing circuitry is configured to measure magnetic coupling properties of a connector with respect to a device. The processing circuitry is configured to obtain indications of the magnetic coupling properties measured by the magnetic sensing circuitry, determine a coupling quality of a connection between the connector and the device based at least on the indications of the magnetic coupling properties, and provide an indication based at least on the coupling quality of the connection falling below a threshold quality level.

In yet another example implementation, an apparatus includes a processing system operatively coupled with one or more computer readable storage media, and program instructions stored on the one or more computer readable storage media. Based on being read and executed by the processing system, the program instructions direct the processing system to at least obtain indications of the magnetic coupling properties from the magnetic sensing circuitry, determine a coupling quality of a connection between the connector and the device based at least on the indications of the magnetic coupling properties, and provide an indication based at least on the coupling quality of the connection falling below a threshold quality level.

This summary is provided to introduce a selection of concepts in a simplified form that are further described below in the detailed description. It may be understood that this summary is not intended to identify key features or essential features of the claimed subject matter, nor is it intended to be used to limit the scope of the claimed subject matter.

### BRIEF DESCRIPTION OF THE DRAWINGS

Many aspects of the disclosure can be better understood with reference to the following drawings. While several implementations are described in connection with these drawings, the disclosure is not limited to the implementations disclosed herein. On the contrary, the intent is to cover all alternatives, modifications, and equivalents.

FIGS. 1A and 1B illustrate an environment to provide identify connector coupling states on a computing system in an implementation.

FIG. 2 illustrates a computing environment to provide connector coupling monitoring for a computing system in an implementation.

FIG. 3 illustrates a set of operations of a computing system to provide connector coupling monitoring in an implementation.

FIG. 4 illustrates a logic structure to manage coupling states and alerts based on the coupling states for a computing system in an implementation.

FIG. 5 illustrates aspects of magnetic components and sensors of a computing system to support connector coupling monitoring in an implementation.

FIG. 6 illustrates aspects of magnetic components and sensors of a computing system to support connector coupling monitoring in an implementation.

FIG. 7 illustrates configurations of a connector and receptacle of a charger and device, respectively, that may be used in an implementation.

FIG. 8 illustrates an example computing system suitable for implementing any of the architectures, platforms, processes, methods, and operational scenarios disclosed herein.

### DETAILED DESCRIPTION

Device charging involves replenishing a battery of electronic devices, such as used in various computing systems, laptops, smartphones, tablets, or wearables. A common method of charging is through a power supply unit (PSU) or power adapter that connects to a power source, such as an electrical outlet, and then converts and transfers electrical energy to a device battery through a charging cable. This process can include wired connections over a proprietary power connection, or instead, this power connection may conform to a standardized power interface, such as promulgated under the USB (Universal Serial Bus) set of standards. In either case, wired connections may include a physical linkage between a connector of the PSU or power adapter and a receptacle or port of the device to be charged. The physical linkage may be achieved by a magnetically attracted coupling connection, a friction-formed coupling connection, or an interlocking coupling connection, among other types of connections.

For example, a PSU may include a magnetic connector having one or more magnets to magnetically couple to corresponding magnets or magnetic material a device. Problematically, magnetically-coupled charging cables and associated connectors commonly attract dust and other particles, which may cover or obstruct electrical contacts of the connector, or prevent proper connection and fitment. This may cause a faulty or unreliable connection between the PSU and the device, charging failure, arcing, and electrical hazards, among other issues. When such issues occur, a user may visually see that a connector might be plugged in correctly and magnetically coupled to the device, but connections internal to the connector might be insufficient for power transfer, or unconnected entirely.

A magnetically coupled connector may also magnetically couple to a device at improper angles or orientations, even if particles or other connector issues are not present. For example, while a magnetically-formed coupling connection may be established between a PSU and a device, the magnetic connector may be misaligned relative to a receptacle of the device, such that electrical pins of the magnetic connector do not align properly with corresponding mating elements of the device in a way required to transfer power from the PSU to the device or transfer power safely between devices. Similarly, when data links or communication interfaces are carried by a magnetically-coupled connection, a visual inspection of a connector interface might show a connection was made, while electrically the connection has not been properly formed or only partially formed. This can lead to data connections not being properly connected, lead to intermittent connectivity problems, or data loss.

In a computing system, monitoring elements can enable the computing system to identify power usage, battery levels, and charging status. However, existing computing systems lack insight into a quality of the connection between a charging cable and the computing system, especially when using magnetically coupled connections. The quality of the connection relates to a three-dimensional connection metric with respect to orientations, angles, skew, or distance. When physical issues with a charger or a receptacle element of the computing system arise, in the present implementations, a connection monitoring system can enable the computing system to detect problems in coupling quality between a cable connector and corresponding connector elements of the computing system. The connection monitoring system can identify coupling properties associated with the connection between the connector and the elements of the computing system. Example coupling properties may include a strength (i.e., magnitude) of a magnetic field produced by magnets of the magnetic connector, a relative orientation of the magnetic field with respect to the elements of the computing system (i.e., vector direction), and the like. These magnetic properties can be related to positioning of a cable connector with respect to a connection of a device, such as the aforementioned orientation, angle, skew, or distance. From this, among other information, determinations can be made as to a quality of a connection, which can indicate if an electrical connection might be insufficient.

Advantageously, the connection detection mechanisms and techniques discussed herein provide technical benefits and technical effects that increase the quality of a connection between a cable and a device, or between devices, as well as reduce risk from faulty connections, such as electrical hazards, charge failure, and the like. These technical benefits and technical effects provide increased reliability and user-awareness of connections between PSUs and computing systems, among other devices and cable/link couplings. As such, enhanced techniques, devices, and systems employing coupling quality monitoring may have the further technical benefits and technical effects of identifying and preventing improper power transfer between a PSU and a computing system to increase battery charge reliability and increase a level of charge provided to battery powered devices.

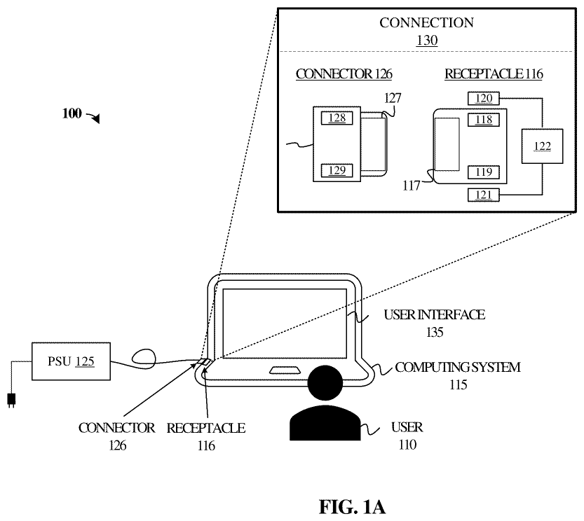

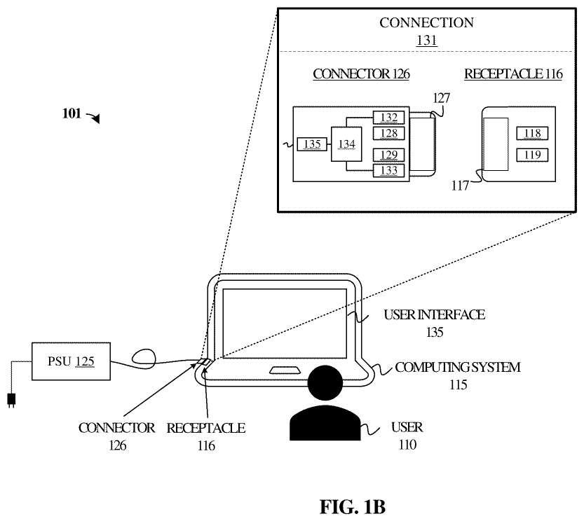

Turning now to various enhanced implementations of techniques, software, systems, and apparatus elements, FIGS. 1A and 1B are presented. FIGS. 1A and 1B illustrate environments to identify connector coupling states on a computing system in an implementation. Although FIGS. 1A and 1B show a particular arrangement of connector plug and socket (or receptacle), it should be understood that other connection nomenclature, gender arrangements, polarities, or configurations can be employed.

FIG. 1A includes environment 100, which includes computing system 115 with user 110, receptacle 116, power supply unit (PSU) 125, and user interface 135. Receptacle 116 and connector 126 may create connection 130 between components thereof. FIG. 1B includes environment 101, which also includes computing system 115 with user 110, receptacle 116, PSU 125, and user interface 135.

In reference to both environments 100 and 101, computing system 110 is representative of a device, such as a laptop, tablet, smartphone, or some other computing system or other electronic device. Computing system 110 can receive source power supplied by power supply unit (PSU) 125 over a wired link, which can supply operating power to computing system 110. In addition to operational power for various elements of computing system 110, PSU 125 can provide power to charge a battery, if included. In general, PSU 125 can convert electrical power from a source (e.g., an electrical outlet) into an appropriate power format needed by computing system 110. This can include power conversion from AC to DC, or among various voltage levels at associated currents. In some examples, a user might connect PSU 125 to a power source for certain periods of time, during which a battery might be able to be charged, and then disconnect PSU 125 from the power source during which the battery provides power to operate computing system 110. Various switchover or power source selection circuitry can be provided in computing system 110 to operate using source power or battery power.

To couple to PSU 125 and receive the source power from PSU 125, computing system 110 includes receptacle 116 capable of interfacing with connector 126 of PSU 125. Both receptacle 116 and connector 126 may include various pins, ports, electronics, and coupling mechanisms configured in accordance with a connection standard or may be proprietary. For example, receptacle 116 and connector 126 may conform to a type of Universal Serial Bus (USB) connection standard to interface with each other, such as USB type C connections which might accommodate power connections with various data interfaces, such as USB, Thunderbolt, or DisplayPort interfaces and other types of connection standards.

As illustrated in environment 100 of FIG. 1A, receptacle 116 and connector 126 may form connection 130 over which the source power may be transferred from PSU 125 to computing system 110, or over which data interfaces can be electrically coupled. Connection 130 can be representative of at least one among a magnetically-formed coupling connection, a friction-formed coupling connection, or an interlocking coupling connection. Receptacle 116 and connector 126 may further be coupled together electrically to transfer the source power from PSU 125 to computing system 110.

Receptacle 116 includes port configuration 117, magnetic elements 118 and 119, magnetic property sensors 120 and 121, and connection monitor 122. Connector 126 includes plug configuration 127 and magnetic elements 128 and 129. Port configuration 117 may be representative of a configuration of ports or sockets corresponding to a connection standard. Similarly, plug configuration 127 may be representative of a configuration of pins (e.g., a pinout) corresponding to the same connection standard. When connector 126 is coupled to receptacle 116, the pins of plug configuration 127 can be inserted into or otherwise coupled to the ports of port configuration 117 to create a physical and electrical coupling connection between connector 126 and receptacle 116. When connection 130 is formed between receptacle 116 and connector 126, magnetic element 118 of receptacle 116 and magnetic element 128 of connector 126 may align with each other along at least one axis, and magnetic element 119 of receptacle 116 and magnetic element 129 of connector 126 may align with each other along at least one axis to create a magnetically coupled mechanical connection between PSU 125 and computing system 110. Magnetic elements 118, 119, 128, and 129 may be representative of permanent magnets, electromagnets, or other types of magnets. Examples of the permanent magnets include neodymium magnets, samarium cobalt magnets, alnico magnets, ceramic magnets, ferrite magnets, and bitter magnets, among others, and the examples herein are not limited to a particular type of magnetic element or magnetic coupling technique.

As magnetic elements 118 and 128 and magnetic elements 119 and 129 are placed near each other, such as when connection 130 is formed or nearly formed, each axial pair of magnetic elements may interact using corresponding magnetic fields having various three-dimensional properties. For example, the properties of the magnetic coupling between receptacle 116 and connector 126 may indicate information about the magnetic field, which may be used to determine a proximity of connector 126 to receptacle 116, an orientation of connector 126 relative to receptacle 116, and the like. Such information may include the strength of the magnetic field and the relative orientation of the magnetic field between receptacle 116 and connector 126. As the magnetic field of each pair of magnetic elements is produced, magnetic property sensors 120 and 121 may be configured to sense the magnetic fields and identify respective magnetic coupling properties of the magnetic elements. More specifically, magnetic property sensor 120 may identify properties of the magnetic field produced between magnetic elements 118 and 128, and magnetic property sensor 121 may identify properties of the magnetic field produced between magnetic elements 119 and 129. Technical benefits and technical effects of measurement of a strength of the magnetic field and a relative orientation of the magnetic field can include the determination of a physical manifestation of a coupling connection strength or alignment between a plug and socket or receptacle.

Magnetic property sensors 120 and 121 may be representative of any type of magnetic, electromagnetic, or other sensor or sensing apparatus that can determine the strength, angle, or orientation of magnetic fields produced in the vicinity of the sensor. For example, magnetic property sensors 120 and 121 may include one or more Hall effect sensors, one or more angle/orientation sensors, or the like. One example of a Hall sensor that can be used in an example implementation includes a TMAG5273 Hall sensor. In other example implementations, receptacle 116 may instead, or in addition, include other types of sensors, such as optical angle sensors, field-detection sensors, proximity sensors, voltage sensors, voltage comparators, current sensors, or other electrical sensors, among other types of sensors, to determine coupling properties between receptacle 116 and connector 126.

Connection monitor 122 may also be included in receptacle 116 to receive magnetic coupling properties sensed by magnetic property sensors 120 and 121 and optionally provide indications of the magnetic coupling properties or indications of coupling status to a control system of computing system 110. Examples of connection monitor 122 include a microprocessor, a microcontroller, a general-purpose processor, a central processing unit (CPU), a digital signal processor (DSP), an application specific integrated circuit (ASIC), field programmable logic device (FPGA), discrete logic, or other circuitry, including combinations or variations thereof.

Computing system 110 can include software capable of obtaining the indications of the magnetic coupling properties or coupling status from connection monitor 122, determining a coupling quality of connection 130 based on at least on the indications of the magnetic coupling properties, and providing an indication to user interface 135 of computing system 110 based at least on the coupling quality of the connection falling below a threshold quality level. In various examples, computing system 110 can determine the coupling quality among several different levels of quality. Technical benefits and technical effects of determinations of different levels of connection quality can include identification and notification of various types or levels of misconnected or improperly coupled connections, specifically those that may prevent charging of a battery, incorrect coupling of communication interfaces. Thus, the quality levels can provide more specific identification of connection issues and more detailed instructions to users on how to remedy such problems.

A first coupling quality can refer to a level of quality wherein the properties of the magnetic fields between magnetic elements 118 and 128 and magnetic elements 119 and 129 satisfy a target coupling distance and the orientations of the magnetic fields satisfy a target relative orientation. The target coupling distance may correspond to a target proximity between receptacle 116 and connector 126 achieved when receptacle 116 and connector 126 are magnetically and/or physically coupled together. The target relative orientation may correspond to a target angle or orientation of the magnetic field achieved when receptacle 116 and connector 126 align with each other in one or more selected axes, such as when receptacle 116 and connector 126 are magnetically and/or physically coupled together with alignment error below a tolerance or target error metric. It follows that when the coupling quality meets the first coupling quality, connector 126 may be considered plugged into receptacle 116 and properly transmitting power from PSU 125 to computing system 110.

Other coupling qualities can refer to levels of quality where either or both the strengths of the magnetic fields and the orientations of the magnetic fields do not satisfy respective targets, and thus, connection 130 between receptacle 116 and connector 126 may be considered improper, unsafe, and power might not be able to be transferred from PSU 125 to computing system 110. For example, a second coupling quality may refer to a level of quality wherein the strengths of the magnetic fields between magnetic elements 118 and 128 and magnetic elements 119 and 129 satisfy a target coupling distance, but the orientations of the magnetic fields do not satisfy a target relative orientation. When an orientation of a magnetic field does not satisfy the target relative orientation, connector 126 might be off-axis, skewed in-plane, or rotated about an axis with respect to different axes relative to receptacle 116. In other words, connector 126 might not be considered as properly plugged into receptacle 116, such that connector 126 is mis-aligned in one of several manners relative to receptacle 116. A third coupling quality may refer to a level of quality wherein the orientations of the magnetic fields between magnetic elements 118 and 128 and magnetic elements 119 and 129 satisfy the target relative orientation, but the strengths of the magnetic fields do not satisfy a target coupling distance. When a strength of a magnetic field does not satisfy the target coupling distance, connector 126 may be too far away from receptacle 116, such that connector 126 is not considered plugged into receptacle 116. A fourth coupling quality may refer to a level of quality wherein neither the strengths nor the orientations of the magnetic fields satisfy respective targets, which may be the case when connector 126 is not present.

In response to determining the coupling quality of connection 130, computing system 110 can provide an indication to user interface 135 based on the level of the coupling quality. More specifically, when the coupling quality includes the first coupling quality, computing system 110 can provide an indication (e.g., a notification) indicating that connector 126 is plugged-in and providing power to computing system 110. When the coupling quality includes any of the second, third, or fourth coupling qualities, computing system 110 can provide an indication indicating that connector 126 is not plugged-in properly and/or not charging properly. In some example implementations, computing system 110 may provide a different notification for each level of coupling quality indicating a respective issue of the coupling and an action to correct the respective issue. For example, computing system 110 may provide a notification that connector 126 is skewed, mis-aligned, or otherwise coupled improperly relative to receptacle 116 based on the coupling quality including the second coupling quality, a notification that connector 126 is too far away relative to receptacle 116 based on the coupling quality including the third coupling quality, or some variation or combination of both notifications based on the coupling quality including the fourth coupling quality. The notifications presented on user interface 135 may include pop-up alerts or notification windows, sounds, and the like.

In some example implementations, computing system 110 may further obtain indications of electrical connection properties of connector 126 with respect to receptacle 116 from connection monitor 122. The electrical connection properties may include information about connection 130, such as a level of conductivity, power, voltage, and/or current received from PSU 125 via connector 126. In such example implementations, computing system 110 can take into account the electrical connection properties when determining the coupling quality of the connection between connector 126 and receptacle 116. Technical benefits and technical effects of determinations of electrical connection properties can further augment the determinations of magnetic connection properties to identify or clarify coupling properties and quality levels, as well as providing more detailed instructions to users for remedies.

In an alternative example implementation, as illustrated in environment 101 of FIG. 1B, receptacle 116 and connector 126 may form connection 131 over which the source power may be transferred from PSU 125 to computing system 110, or over which data interfaces can be electrically coupled. Connection 131 can be representative of at least one among a magnetically-formed coupling connection, a friction-formed coupling connection, or an interlocking coupling connection. Receptacle 116 and connector 126 can further be coupled together electrically to transfer the source power from PSU 125 to computing system 110.

In the example implementation of environment 101, receptacle 116 includes magnetic elements 118 and 119, and connector 126 includes magnetic elements 128 and 129, magnetic property sensors 132 and 133, connection monitor 134, and indicator 135. As magnetic elements 118 and 128 and magnetic elements 119 and 129 are placed near each other, such as when connection 131 is formed or nearly formed, each pair of magnetic elements may create a magnetic field having various properties. Magnetic property sensors 132 and 133 may be configured to sense the magnetic fields and identify respective magnetic coupling properties of the magnets. For example, magnetic property sensor 132 may identify properties of the magnetic field produced between magnetic elements 118 and 128, and magnetic property sensor 133 may identify properties of the magnetic field produced between magnets 119 and 129. Magnetic property sensors 132 and 133 may be representative of any type of sensing devices that can determine the strength, angle, and/or orientation of magnetic fields produced between a pair of magnets. For example, magnetic property sensors 132 and 133 may include one or more Hall sensors, one or more angle/orientation sensors, or other sensors.

Connector 126 can also include connection monitor 134 to receive indications of the magnetic coupling properties sensed by magnetic property sensors 132 and 133. Examples of connection monitor 134 include a microprocessor, microcontroller, general-purpose processor, CPU, DSP, ASIC, FPGA, discrete logic, circuitry, or combinations and variations thereof. In operation, connection monitor 134 may be configured to determine the coupling quality of connection 131 based on at least on the measurements of the magnetic coupling properties and instruct indicator 135 to provide one or more indications of the coupling quality based at least on the coupling quality of the connection falling below a threshold quality level. Indicator 135 may be configured to output an indication based on the received instructions from connection monitor 134. In some examples, indicator 135 may be representative of a device capable of producing the indication, such as an indicator light, speaker, vibration device, digital display, dial, meter, or some other indication device responsive to the coupling quality between receptacle 116 and connector 126 falling below the threshold quality level (e.g., one of the second, third, or fourth coupling qualities described above).

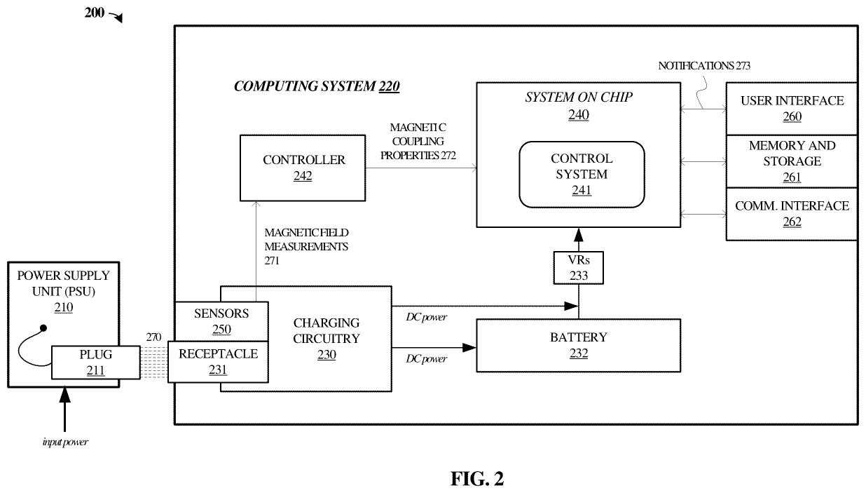

FIG. 2 illustrates another example computing environment 200 for which connector coupling quality monitoring can be implemented. Computing environment 200 can provide connector coupling quality identification and notification for a computing system in an implementation. Computing environment 200 can be an example implementation of environments 100 and 101, although variations are possible.

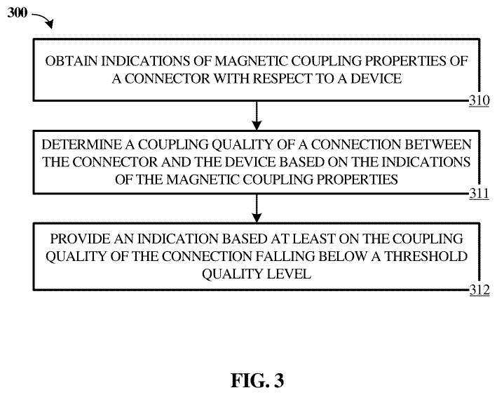

Computing environment 200 includes power supply unit (PSU) 210 coupled over link 270 to computing system 220. PSU 210 includes plug 211. Computing system 220 includes charging circuitry 230, controller 242, sensors 250, system-on-chip (SoC) 240, optional battery 232, voltage regulators (VRs) 233, user interface 260, memory and storage 261, and communication interface 262. Charging circuitry 230 includes receptacle 231. Computing environment 200 further includes various signaling or messaging for conveying magnetic and electrical coupling properties among the various elements, such as magnetic field measurements 271, magnetic coupling properties 272, and notifications 273. SoC 240 provides at least control system 241, with example operations described below with respect to FIG. 3. Although demonstrated as implemented within SoC 240, control system 241 can be implemented on another element of computing system 220, such as controller 242, a dedicated processor, or other processing element, including combinations thereof.

In computing environment 200, PSU 210 is connected to computing system 220 to supply power to computing system 220 via plug 211. Charging circuitry 230 on computing system 220 receives the power provided by PSU 220 via receptacle 231 and allocates portions of the power to battery 232 (when included) and SoC 240. Here, controller 242 receives and manages information from different systems and elements within computing system 220, including sensors 250 that provide magnetic and electrical coupling properties of a connection between PSU 210 and charging circuitry 230, among other information. Controller 242 communicates with SoC 240 to provide magnetic coupling properties 272 which can indicate properties of a coupling quality level between PSU 210 and charging circuitry 230, or more specifically, between plug 211 and receptacle 231.

Other elements in computing system 220 include user interface 260. User interface 260 may include a keyboard, microphone, display screen, mouse, touch pad, touch screen, voice input, accessibility interface, natural language interface, API, or other user input/output apparatus. User interface 260 provides input/output information to SoC 240 associated with operations of computing system 220 through provided user interface elements. User interface 260 further provides coupling quality information or indications to a user through a display screen or other user interface element of user interface 260. The coupling quality information may be provided as an indication, notification, or alert, such as through a pop-up window, icon, flag, sound, alert, vibration, or some other type of indication. The coupling quality information may refer to a state or coupling quality level between PSU 210 and charging circuitry 230, or more specifically, between plug 211 and receptacle 231.

Computing system 220 further includes memory and storage 261 that is coupled to SoC 240. Memory and storage 261 may include volatile and nonvolatile, removable, and non-removable media implemented in any method or technology for storage of information, such as computer readable instructions, data structures, program modules, or other data. Memory and storage 261 may be implemented as a single storage device but may also be implemented across multiple storage devices or sub-systems. Memory and storage 261 may comprise additional elements, such as a controller to read operating software from the storage systems. Examples of storage media include random access memory (RAM), read only memory (ROM), magnetic storage devices, optical storage devices, solid state storage devices, or flash memory, as well as any combination or variation thereof, or any other type of storage media. In some implementations, the storage media may be a non-transitory storage media, but in no case does the storage media comprise propagated signal. Memory and storage 261 stores at least program instructions to support control system 241 executed by SoC 240. Other software stored in memory and storage 261 includes an operating system, utilities, drivers, network interfaces, applications, or other types of software. SoC 240 can comprise microprocessors, central processing units (CPUs), graphics processing units (GPUs), programmable logic units, application specific integrated circuits, or other circuitry capable of supporting the operations described herein. Power controller 242 can comprise similar elements as SoC 240, or can include a microcontroller, among other elements.

Computing system 220 also includes communication interface 262 coupled to SoC 240. Communication interface 262 comprises components that communicate over communication links, such as wired, optical, or wireless network interfaces, network ports, radio frequency (RF) links, processing circuitry and software, or some other communication devices. Communication interface 262 may be configured to use Internet Protocol (IP), Ethernet, optical networking, wireless protocols, communication signaling, or some other communication format, including combinations thereof. Communication interface 262 can communicate with other computing systems, routers, switches, and the like.

In computing environment 200, control system 241 is configured to use magnetic measurements 271 to determine a coupling quality of a connection between plug 211 of PSU 210 and receptacle 231 of charging circuitry 230. Plug 211 may include one or more magnetic elements, and receptacle 231 may include one or more magnetic elements. When plug 211 and receptacle 231 are in proximity relative to one another, sensors 250 can sense magnetic measurements 271, which can be provided to SoC 240 via controller 242. A proper or successful connection may refer to when plug 211 is aligned with receptacle 231 and magnetically, electrically, and/or physically coupled to receptacle 231, such that power can transfer from PSU 210 to charging circuitry 230 without failures or hazards. An improper or poor connection may refer to when plug 211 is misaligned with receptacle 231 along one or more axes and/or not magnetically, electrically, or physically coupled to receptacle 231, such that power cannot transfer from PSU 210 to charging circuitry 230.

By way of a first example, a user properly couples plug 211 to receptacle 231 to provide power from PSU 210 to charging circuitry 230 to power computing system 220. Sensors 250 can sense magnetic field properties between plug 211 and receptacle 231, which can be provided as magnetic field measurements 271 to controller 242. Magnetic measurements 271 may include information about a magnetic field produced between magnetic elements in plug 211 and receptacle 231, such as the strength of the magnetic field and the orientation of the magnetic field. Controller 242 can provide these magnetic field measurements 271 to SoC 240 as magnetic coupling properties 272. Magnetic coupling properties 272 can be provided in a selected data format or digital representation, which may include performing various analog-to-digital conversion processes on magnetic field measurements 271, or other pre-processing including debounce, de-noise, filtering, dynamic range adjustment, data conversion, data interfacing and protocol encapsulation, and other operations.

Based on magnetic coupling properties 272, SoC 240 can determine a coupling quality of the connection between plug 211 and receptacle 231 based on at least on the data represented by magnetic field measurements 271. In this example, SoC 240 may determine that the coupling quality exceeds a threshold quality level, such as the strength of the magnetic field satisfies a target coupling distance (i.e., plug 211 is within a threshold proximity to receptacle 231 (e.g., plugged-in)) and the orientation of the magnetic field satisfies a target relative orientation (i.e., plug 211 is aligned with receptacle 231 relative to at least one axis).

By way of a second example, a user improperly couples plug 211 to receptacle 231 despite an attempt to provide power from PSU 210 to charging circuitry 230 to power computing system 220. In this example, magnetic field measurements 271 are provided to controller 242 and controller 242 provides magnetic coupling properties 272 to SoC 240. From here, SoC 240 can determine that magnetic coupling properties 272 can indicate either the strength of the magnetic field does not satisfy the target coupling distance (i.e., plug 211 is too far away from receptacle 231) or the orientation of the magnetic field does not satisfy the target relative orientation (i.e., plug 211 is misaligned or skewed relative to receptacle 231), or both. Accordingly, SoC 240 can determine that the coupling quality falls below a threshold quality level.

In both examples above, SoC 240 can provide alerts or notifications 273 to user interface 260 based on the coupling quality level of the connection between plug 211 and receptacle 231. Following the first example, SoC 240 may present to a user, via user interface 260, a notification that plug 211 and receptacle 231 are connected properly and that charging circuitry 230 is receiving power from PSU 210. Following the second example, SoC 240 may present to the user, via user interface 260, a notification that plug 211 is not properly connected to receptacle 231, and thus, charging circuitry 230 is not receiving power from PSU 210. Other indications and notifications may be presented on user interface 260 based on at least the coupling quality.

FIG. 3 illustrates a set of operations of a computing system to provide connector coupling monitoring in an implementation. While the operations of FIG. 3 are referenced below with respect to elements of FIG. 2, it should be understood that these operations can apply to elements of FIG. 1 or to other elements described herein.

In operation 310, control system 241 obtains indications of magnetic measurements 271 with respect to plug 211 and receptacle 231. In various example implementations, receptacle plug 211 and receptacle 231 each include magnetic elements to form a magnetically coupled connection between PSU 210 and computing system 220. As plug 211 and receptacle 231 are brought together, the magnetic elements exhibit a changing magnetic field configuration. Sensors 250 may be configured to sense magnetic properties of the changing magnetic field configurations, which may include information such as the strength of the magnetic field and the relative orientation of the magnetic field between plug 211 and receptacle 231. Control system 231 may obtain magnetic measurements 271 from sensors 250 via controller 242.

In operation 311, control system 241 determines a coupling quality of a connection between plug 211 and receptacle 231. More particularly, control system 241 may determine the coupling quality among several different quality levels. A first coupling quality may refer to a quality level where the strength of the magnetic field produced by the magnets of plug 211 and receptacle 231 satisfy a target coupling distance and where the orientation of the magnetic field satisfies a target relative orientation. The target coupling distance may correspond to a proximity between plug 211 and receptacle 231 when the two are magnetically and/or physically coupled together. The target relative orientation may correspond to an angle or orientation of the magnetic field observed when plug 211 and receptacle 231 align with each other in at least one axis, such as when plug 211 and receptacle 231 are magnetically and/or physically coupled together without misalignment.

Other coupling quality statuses may refer to quality levels where either or both the strength of the magnetic field and the orientation of the magnetic field do not satisfy respective targets, and thus, the connection between plug 211 and receptacle 231 may be improper, unsafe, and power might not be transmitted from PSU 210 to charging circuitry 230. For example, a second coupling quality may refer to a quality level where the strength of the magnetic field satisfies the target coupling distance, but the orientation of the magnetic field does not satisfy the target relative orientation. When an orientation of a magnetic field does not satisfy the target relative orientation, plug 211 may be off-axis, skewed in-plane, or axially rotated with relative to a preferred orientation for receptacle 231. In other words, plug 211 might not be properly plugged into receptacle 231, such that plug 211 is skewed in one of several directions relative to receptacle 231. A third coupling quality may refer to a quality level where the orientation of the magnetic field satisfies the target relative orientation, but the strength of the magnetic field does not satisfy the target coupling distance. The strength of a magnetic field might not satisfy the target coupling distance if plug 211 is too far away from receptacle 231, such that plug 211 is not fully seated into receptacle 231. A fourth coupling quality may refer to a level of quality wherein neither the strength nor the orientation of the magnetic field satisfies respective targets.

In operation 312, control system 241 provides a notification through user interface 260 based on at least the determined coupling quality falling below a threshold quality level. In various examples, the threshold quality level may correspond to a quality level meeting or exceeding the first coupling quality as described above. It follows that the second, third, and fourth coupling qualities may fall below the threshold quality level. In such cases, control system 241 may provide an indication to a user that a connection between plug 211 and receptacle 231 is unsuccessful or improper, and thus, that charging might not occur unless and until the coupling quality is remedied above the threshold quality level.

In some example implementations, control system 241 may provide a different indication for each level of coupling quality. For example, control system 241 may provide a notification that plug 211 is skewed or otherwise coupled improperly relative to receptacle 231 based on the coupling quality including the second coupling quality, a notification that plug 211 is too far away relative to receptacle 231 based on the coupling quality including the third coupling quality, or some variation or combination of both notifications based on the coupling quality including the fourth coupling quality.

In some example implementations, control system 241 may further provide an indication based on the determined coupling quality meeting the threshold quality level (i.e., the connection between plug 211 and receptacle 231 has a coupling quality of the first coupling quality). Like other indications, this indication may be presented on user interface 260 as a notification that may include a pop-alert, a notification window, a sound, or the like, that indicates successful connection and charging between PSU 210 and computing system 220.

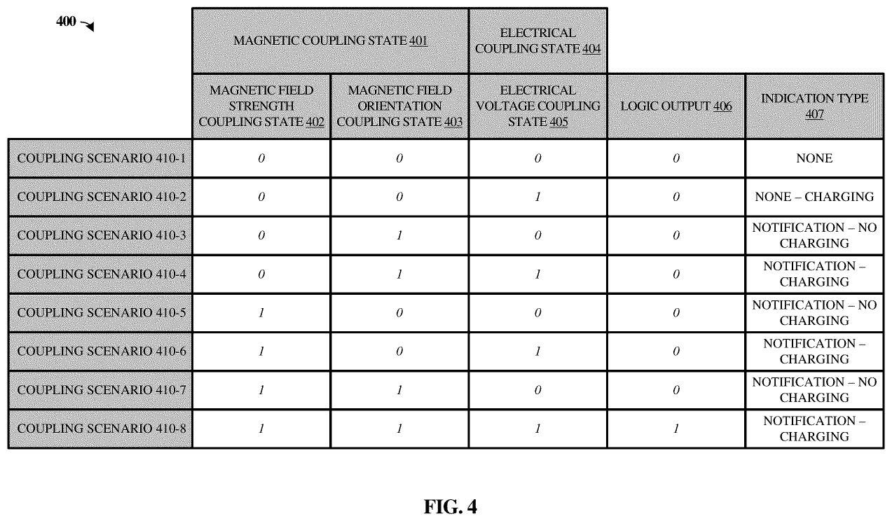

FIG. 4 illustrates a logic structure to determine coupling quality and manage alerts based on the coupling quality for a computing system in an implementation. FIG. 4 includes table 400, which includes logical state values for various coupling scenarios 410. Table 400 further includes logical output 406 based on each logical state value and includes indication type 407 based on logical output 406 and the other logical state values.

Each of coupling scenarios 410 may exemplify a different connection state between a plug of a power supply unit (PSU) and a receptacle of a device. For example, coupling scenarios 410 may include example connections between connector 126 and receptacle 116 of FIGS. 1A and 1B and/or plug 211 and receptacle 231 of FIG. 2. Logic output 406 may include a logical low state (“0”) if the connector is not magnetically coupled to the receptacle, not electrically coupled to the receptacle, or both. It follows that logic output 406 may include a logical high state (“1”) only if the connector is both magnetically and electrically coupled to the receptacle. Logic output 406 may be determined using factors related to magnetic coupling state 401 and electrical coupling state 404 for each of coupling scenarios 410.

Magnetic coupling state 401 may include magnetic field strength coupling state 402 and magnetic field orientation coupling state 402. In various example implementations, a connector and a receptacle may each include one or more magnetic elements, which can be used to magnetically couple the two endpoints together. Magnetic field strength coupling state 402 corresponds to a strength or magnitude of the magnetic field produced by the magnetic elements of the connector and receptacle. If magnetic field strength coupling state 402 includes a logical low state, the strength of the magnetic field does not satisfy a target coupling distance. In other words, this may mean the connector is not within a threshold proximity relative to the receptacle such that a magnetic connection is not made, and thus, the strength of the magnetic field is weak compared to the strength of the magnetic field when the connector is magnetically coupled to the receptacle. If the magnetic field strength coupling state 402 includes a logical high state, the strength of the magnetic field satisfies the target coupling distance, such that a magnetic connection is made between the connector and the receptacle. Magnetic field orientation coupling state 403 corresponds to an angle or orientation of the magnetic field produced by the magnets of the connector and receptacle. If magnetic field orientation coupling state 403 includes a logical low state, the orientation of the magnetic field does not satisfy a target relative orientation. In other words, this may mean that the connector is not oriented properly with respect to the receptacle (e.g., skewed, rotated, tilted, etc.). If magnetic field orientation coupling state 403 includes a logical high state, the orientation of the magnetic field satisfies the target relative orientation, such that the connection angle between the connector and the receptacle is proper to establish a connection.

Electrical coupling state 404 may include electrical voltage coupling state 405. Electrical voltage coupling state 405 may relate to whether a target voltage is reached between the connector and the receptacle, or whether a link interface has been established between the connector and the receptacle. For example, electrical voltage coupling state 405 may include a logical low state if an electrical connection is not made between the connector and the receptacle, such that no power is transferred from the PSU to the device or no link interface has been established. On the other hand, electrical voltage coupling state 405 may include a logical high state if an electrical connection is made between the connector and the receptacle, such that signals from the PSU to the device meet the target voltage, and thus, the device can receive power.

Coupling scenario 410-1 represents a first connection state between a connector and a receptacle. In coupling scenario 410-1, each of magnetic field strength coupling state 402, magnetic field orientation coupling state 403, and electrical voltage coupling state 405 includes a logical low state. Accordingly, the connector is neither magnetically coupled nor electrically coupled to the receptacle. Thus, logic output 406 includes a logical low state based on each of the other logical low states. A control system of the device (e.g., control system 241) might not present an indication on a user interface of the device to notify a user about the connection state in coupling scenario 410-1.

Coupling scenario 410-2 represents a second connection state between a connector and a receptacle. In coupling scenario 410-2, magnetic field strength coupling state 402 and magnetic field orientation coupling state 403 include logical low states while electrical voltage coupling state 405 includes a logical high state. Based on these connection state values, the connector is not magnetically coupled to the receptacle but is electrically coupled to the receptacle. Thus, logic output 406 includes a logical low state based on each of the other logical states. The control system of the device might not present an indication on a user interface of the device to notify a user about the connection state in coupling scenario 410-2, however, the device may be charging, nevertheless.

Coupling scenario 410-3 represents a third connection state between a connector and a receptacle. In coupling scenario 410-3, magnetic field strength coupling state 402 and electrical voltage coupling state 405 include logical low states while magnetic field orientation coupling state 403 includes a logical high state. Based on these connection state values, the connector is not magnetically or electrically coupled to the receptacle despite the orientation of the connector satisfying the target relative orientation. Thus, logic output 406 includes a logical low state based on each of the other logical states. The control system of the device may present an indication on the user interface of the device to notify a user about the connection state in coupling scenario 410-3 (e.g., not electrically or magnetically coupled) and to notify the user to check and/or clean the connector. Indication type 407 may include a notification, such as a pop-up window, alerting the user that the PSU is not charging the device.

Coupling scenario 410-4 represents a fourth connection state between a connector and a receptacle. In coupling scenario 410-4, magnetic field strength coupling state 402 includes a logical low state while magnetic field orientation coupling state 403 and electrical voltage coupling state 405 include logical high states. Based on these connection state values, the connector is not magnetically coupled to the receptacle despite the orientation of the connector satisfying the target relative orientation, but the connector is electrically coupled to the receptacle. Thus, logic output 406 includes a logical low state based on each of the other logical states. The control system of the device may present an indication on the user interface of the device to notify a user about the connection state in coupling scenario 410-4 (e.g., electrically coupled, not magnetically coupled) and to notify the user to check and/or clean the connector. For example, indication type 407 may include a notification, such as a pop-up window, alerting the user that the PSU is charging the device.

Coupling scenario 410-5 represents a fifth connection state between a connector and a receptacle. In coupling scenario 410-5, magnetic field strength coupling state 402 includes a logical high state while magnetic field orientation coupling state 403 and electrical voltage coupling state 405 include logical low states. Based on these connection state values, the connector is within a target proximity relative to the device, however the orientation of the connector does not satisfy the target relative orientation. Further, the connector is not electrically coupled to the receptacle. Thus, logic output 406 includes a logical low state based on each of the other logical states. The control system of the device may present an indication on the user interface of the device to notify a user about the connection state in coupling scenario 410-5 (e.g., not electrically or magnetically coupled) and to notify the user to check and/or clean the connector. For example, indication type 407 may include a notification, such as a pop-up window, alerting the user that the PSU is not charging the device.

Coupling scenario 410-6 represents a sixth connection state between a connector and a receptacle. In coupling scenario 410-6, magnetic field strength coupling state 402 and electrical voltage coupling state 405 include logical high states while magnetic field orientation coupling state 403 includes logical low states. Based on these connection state values, the connector is within a target proximity relative to the device and is electrically coupled to the receptacle, however, the orientation of the connector does not satisfy the target relative orientation. Thus, logic output 406 includes a logical low state based on each of the other logical states. The control system of the device may present an indication on the user interface of the device to notify a user about the connection state in coupling scenario 410-6 (e.g., electrically coupled, not magnetically coupled) and to notify the user to check and/or clean the connector. For example, indication type 407 may include a notification, such as a pop-up window, alerting the user that the PSU is charging the device.

Coupling scenario 410-7 represents a seventh connection state between a connector and a receptacle. In coupling scenario 410-7, magnetic field strength coupling state 402 and magnetic field orientation coupling state 403 include logical high states while electrical voltage coupling state 405 includes a logical low state. Based on these connection state values, the connector is magnetically coupled to the receptacle, but is not electrically coupled to the receptacle. Thus, logic output 406 includes a logical low state based on each of the other logical states. The control system of the device may present an indication on the user interface of the device to notify a user about the connection state in coupling scenario 410-7 (e.g., magnetically coupled, not electrically coupled) and to notify the user to check and/or clean the connector. For example, indication type 407 may include a notification, such as a pop-up window, alerting the user that the PSU is not charging the device.

Coupling scenario 410-8 represents an eighth connection state between a connector and a receptacle. In coupling scenario 410-8, magnetic field strength coupling state 402, magnetic field orientation coupling state 403, and electrical voltage coupling state 405 all include logical high states. Based on these connection state values, the connector is both magnetically and electrically coupled to the receptacle. Thus, logic output 406 includes a logical high state based on each of the other logical high states. The control system of the device may present an indication on the user interface of the device to notify a user about the connection state in coupling scenario 410-8 (e.g., electrically and magnetically coupled). For example, indication type 407 may include a notification, such as a pop-up window, alerting the user that the PSU is charging the device.

The control system of the device may provide additional or different notifications based on the values of the coupling states and logical output 406. For example, indication type 407 may also, or instead, include notifications indicating successful or improper connections based on magnetic coupling states 401 and/or electrical coupling states 404, such as notifications indicating detection of correct magnetic orientation, correct magnetic strength, and/or electrical connection. The notifications may further notify the user to re-connect the connector to the device after checking, cleaning, and/or correcting the coupling between the connector and the device. Other combinations or variations thereof may be contemplated.

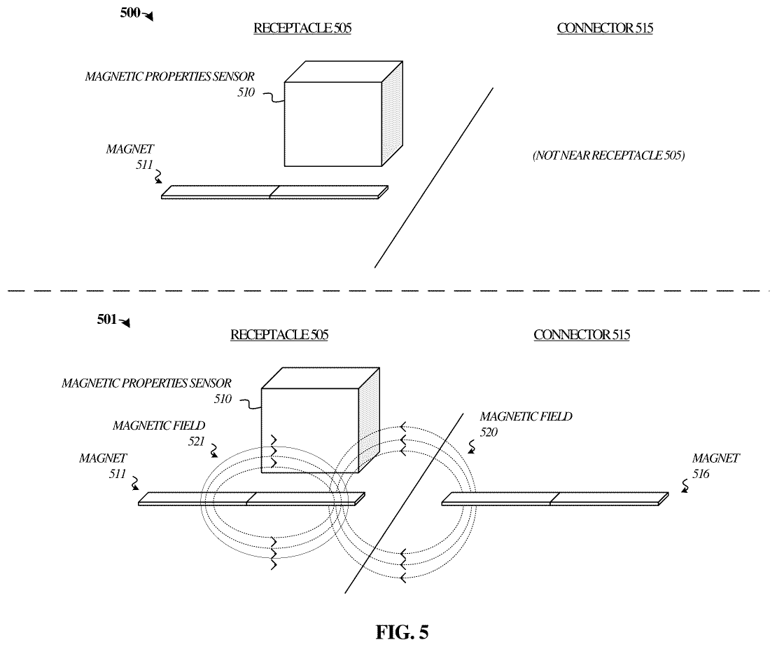

FIG. 5 illustrates arrangements of magnetic components and sensors of a computing system to support connector coupling monitoring in an implementation. FIG. 5 includes arrangements 500 and 501. Arrangement 500 includes receptacle 505, which includes magnetic properties sensor 510 and magnet 511. Arrangement 501 includes receptacle 505 and connector 515, which includes magnet 516.

In general, receptacle 505 may be representative of a receptacle or port of a computing system that includes magnetic properties sensor 510 and magnet 511. The computing system may be representative of a user device, such as a laptop, tablet, smartphone, or some other computing system, such as computing system 110 of FIGS. 1A and 1B. The computing system can receive source power supplied by a power supply unit (PSU) over a wired link, which can supply operating power to the computing system via connector 515. Connector 515, as illustrated in arrangement 501, includes magnet 516. In various example implementations, receptacle 505 and connector 515 can magnetically couple together via magnets 511 and 516 and can further electrically couple together to transfer the source power from the PSU to the computing system. While not shown, both receptacle 505 and connector 515 can include various pins, ports, and electronics arranged in accordance with a standardized connection specification (e.g., the USB-C connection standard, among others)

Magnets 511 and 516 may be representative of permanent magnets, electromagnets, or other types of magnets capable of forming a magnetic connection between receptacle 505 and connector 515. Examples of the magnets include the various types discussed herein. Magnetic properties sensor 510 may be representative of any type of sensing devices that can determine the strength, angle, and/or orientation of magnetic field 520 produced between magnets 511 and 516. For example, magnetic properties sensor 510 may include one or more Hall effect sensors, one or more angle/orientation sensors, or the like.

Arrangement 500 represents a scenario where connector 515 is not near receptacle 505, and thus, no connection is established between connector 515 and receptacle 505. Accordingly, magnetic properties sensor 510 might not sense any magnetic coupling properties, such as magnetic field strength or magnetic field orientation.

Arrangement 501 represents a different scenario where connector 515 is plugged-into receptacle 505. Thus, a magnetically formed coupling connection is established via magnets 511 and 516. When magnet 516 comes near magnet 511, such as when the connection is established, magnets 511 and 516 produce magnetic fields 520 and 521. Magnetic field 520 may be a magnetic field having a first strength and orientation created between magnet 516 and magnet 511. Magnetic field 521 may be another magnetic field having a second strength and orientation created between opposite polarity portions of magnet 511. When magnetic fields 520 and 521 are produced, magnetic properties sensor 510 can identify magnetic properties of the magnetic fields, such as the strengths and orientations. Although not shown, magnetic properties sensor 510 may be coupled to provide such magnetic properties to a control system of the computing system (e.g., control system 241). The control system can determine a coupling quality of the connection between connector 515 and receptacle 505 based on the sensed magnetic properties to evaluate whether a proper and successful connection has been formed to allow power transfer from the PSU to the computing system.

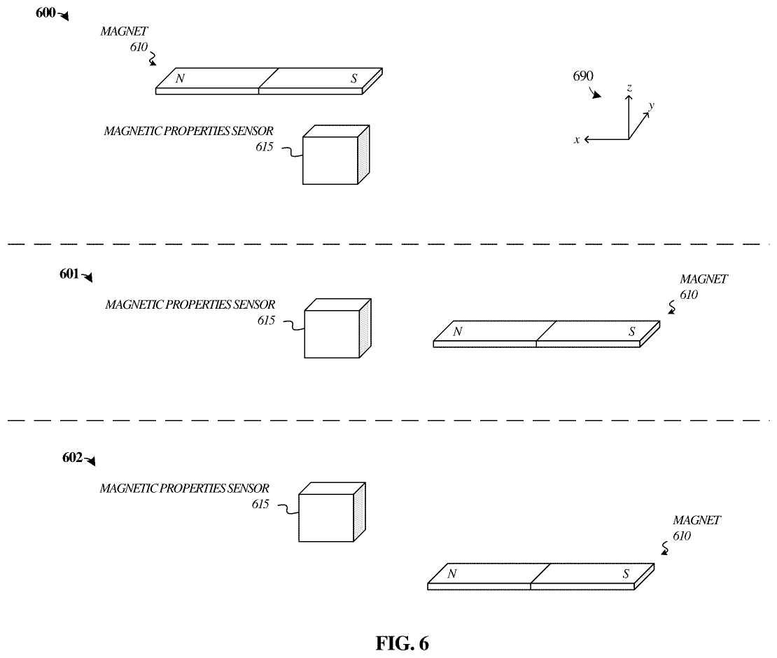

FIG. 6 illustrates arrangements of magnetic components and sensors of a computing system to support connector coupling monitoring in an implementation. FIG. 6 includes arrangements 600, 601, and 602, which each illustrate magnet 610 and magnetic properties sensor 615 in various positions and orientations relative to one another and with respect to coordinate frame 690. Other arrangements are possible than those shown in FIG. 6, such as rotated arrangements, skewed in-plane arrangements, and other three-dimensional arrangements, including combinations thereof.

Arrangement 600 illustrates magnet 610 positioned on-axis relative to magnetic properties sensor 615 and with respect to the y-axis of coordinate frame 690. In this configuration, when another magnet is placed in proximity to magnet 610 and in parallel to magnet 610 with respect to the x-axis of coordinate frame 690, magnetic properties sensor 615 may sense properties of a magnetic field in both the x-axis and the y-axis that are approximately 90-degrees out-of-phase relative to one another. For example, magnetic properties sensor 615 may measure a magnetic flux density property of the magnetic field in both axes.

Arrangement 601 illustrates magnet 610 positioned in-plane relative to magnetic properties sensor 615 with respect to the y-axis of coordinate frame 690 and in parallel relative to magnetic properties sensor 615 with respect to the x-axis of coordinate frame 690. In this configuration, when another magnet is placed in proximity to magnet 610 and in parallel to magnet 610 with respect to the x-axis of coordinate frame 690, magnetic properties sensor 615 may sense properties of a magnetic field in both the x-axis and the y-axis that are approximately 90-degrees out-of-phase relative to one another. However, in this configuration, magnetic properties sensor 615 may measure a different amount of magnetic flux density of the magnetic field in both axes.

Arrangement 602 illustrates magnet 610 positioned off-axis relative to magnetic properties sensor 615 with respect to coordinate frame 690. In this configuration, when another magnet is placed in proximity to magnet 610 and in parallel to magnet 610 with respect to the x-axis of coordinate frame 690, magnetic properties sensor 615 may sense properties of a magnetic field in each axis. For example, magnetic properties sensor 615 may measure magnetic flux density in each of the x-axis, y-axis, and the z-axis. The measurements of magnetic flux density in the x-direction and z-direction may be in-phase relative to one another but approximately 90-degrees out-of-phase relative to the y-direction magnetic flux density. Each amplitude of the magnetic flux densities may also be different.

In various example implementations, a computing system that includes magnetic properties sensor 615 can determine a coupling quality of a magnetic connection between the computing system and the PSU based on the measurements obtained by magnetic properties sensor 615. Target property values of the magnetic field (e.g., target magnetic field strength, target relative orientation) with which to evaluate against measured magnetic properties, may be determined based on a selected configuration for magnetic properties sensor 615.

In various implementations, a computing system can employ artificial intelligence (AI) and/or machine learning techniques, such as large language models (LLMs) or Generative Pre-Trained Transformers (GPTs), to determine parameters surrounding the coupling quality of a magnetic connections between a computing system and a PSU. For example, the computing system may utilize one or more neural networks, classification models, regression models, deep learning algorithms, or the like, trained based on various connection orientations with respect to magnetic field configurations, such as those illustrated in FIGS. 5 and 6. The modeling elements may further be provided inputs including characteristics of magnetic elements and magnetic property sensors used in the connection between the computing system and the PSU. Accordingly, as magnetic property sensors measure magnetic fields produced in the vicinity of the sensors, the computing system can predict a coupling quality and notify a user of the coupling quality based on the prediction made using such techniques. These predictions can be based on training performed for past connection attempts across a single device or many devices, and can identify pattern-based intelligence related to magnetic field properties and coupling quality. In this manner, machine learning or similar techniques can be applied to interpret magnetic field measurements, or orientations, positionings, skews, and angles among endpoints of a connection to determine a connection quality. The quality can be determined in the various terms and gradations discussed herein.

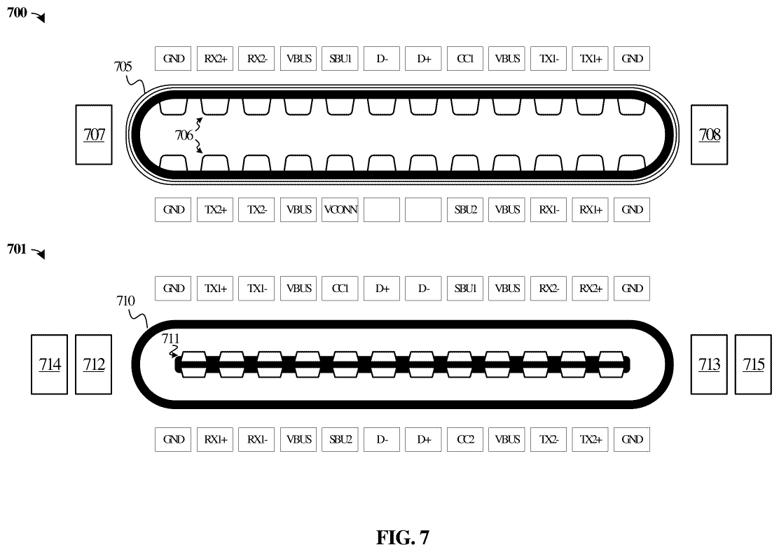

FIG. 7 illustrates end view pinout configurations of a plug and receptacle that may be used in an implementation. FIG. 7 includes plug configuration 700 and receptacle configuration 701. Plug configuration 700 may be used in any connector device described herein, such as connector 126 of FIGS. 1A and 1B or plug 211 of FIG. 2. Receptacle configuration 701 may be used in any receptacle or port of a device described herein, such as receptacle 116 of computing system 110 or receptacle 231 of computing system 220. Other configurations may also be used, such as reversed arrangements.

In various examples, plug configuration 700 is representative of a pinout of a male plug, and receptacle configuration 701 is representative of a pinout of a female port. More specifically, these configurations illustrate an arrangement of components (e.g., pins 706, pins 711) in accordance with a Universal Serial Bus (USB) type-C(USB-C) connection standard that can be used to transfer data and power between endpoints. Thus, the pin descriptions are omitted for brevity herein, but various pins can be dedicated to power (e.g., VBUS, VCONN, GND) and dedicated to data transfer (e.g., TX, RX, GND, etc.). Also, CC1 and CC2 can be employed to establish and manage electrical connection link status to detect electrical attachment or detachment of plug configuration 700 with respect to receptacle configuration 701.

A link configured with plug configuration 700 may include body 705, pins 706, and magnetic elements 707 and 708. Body 705 may be representative of a protective housing or frame that holds and/or covers pins 706 of the link. Magnetic elements 707 and 708 may be representative of one or more of the various types of magnetic elements described herein. Although magnetic elements 707 and 708 are illustrated as being adjacent to and external to body 705, magnetic elements 707 and 708 may be arranged in various ways internally or externally with respect to body 705.

A receptacle configured with receptacle configuration 701 may include body 710, pins 711, magnetic elements 712 and 713, and magnetic property sensors 714 and 715. Body 710 may also be representative of a protective housing or frame that holds and/or covers pins 711 of the receptacle. Magnetic elements 712 and 713 may be representative of one or more of the various types of magnetic elements described herein and may be arranged in various ways inside or outside body 710.

In various example implementations, a link configured with plug configuration 700 can be electrically and physically coupled to a receptacle configured with receptacle configuration 701 via pins 706 and 711, respectively. However, if the receptacle and plug are misaligned with respect to some axis or the plug is not fully inserted into the receptacle, power or data transfer might not occur properly between endpoints. In such examples, magnetic elements 712 and 713 can be arranged such that when a coupling is made between the link and receptacle, magnetic elements 707 and 712 align with each other along at least one axis and magnetic elements 708 and 713 align with each other along at least one axis to create a magnetically coupled mechanical connection between the link and the receptacle.

As a link and a receptacle are placed near each other, such as when an electrical, physical, and/or magnetic connection is formed or nearly formed, each axial pair of magnetic elements may interact using corresponding magnetic fields having various three-dimensional properties. As the magnetic field of each pair of magnetic elements is produced, magnetic property sensors 714 and 715 (e.g., Hall effect sensors) may be configured to sense the magnetic fields and identify respective magnetic coupling properties of the magnetic elements. More specifically, magnetic property sensor 714 may identify properties of the magnetic field produced between magnetic elements 707 and 712, and magnetic property sensor 715 may identify properties of the magnetic field produced between magnetic elements 708 and 713.

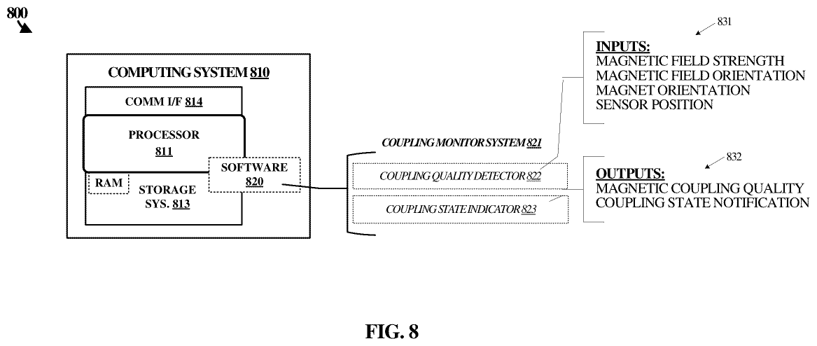

FIG. 8 illustrates an example computing system 800 suitable for implementing any of the architectures, platforms, processes, methods, and operational scenarios disclosed herein. For example, computing system 810 can be used to implement elements of computing system 110 of FIG. 1 or elements of computing system 220 of FIG. 2.

Examples of computing system 810 include, but are not limited to, laptop computing devices, tablet computing devices, smartphone devices, portable computing devices, or any other electronic device with chargeable batteries, as well as any other type of physical or virtual machine, and other computing systems and devices, as well as any variation or combination thereof. Computing system 810 may be implemented as a single apparatus, system, or device or may be implemented in a distributed manner as multiple apparatuses, systems, or devices. Computing system 810 includes, but is not limited to, processor 811, storage system 813, communication interface system 814, and software 820. Processor 811 is operatively coupled with storage system 813 and communication interface system 814.

Processor 811 loads and executes software 820 from storage system 813. Software 820 includes coupling monitor system 821, which is representative of various enhanced operations and processes discussed with respect to the preceding Figures. When executed by processor 811 to monitor connector coupling quality in a computing system, software 820 directs processor 811 to operate as described herein for at least the various processes, operational scenarios, and sequences discussed in the foregoing implementations. Computing system 810 may optionally include additional devices, features, or functionality not discussed for purposes of brevity.

Referring still to FIG. 8, processor 811 may comprise processing circuitry that retrieves and executes software 820 from storage system 813. Processor 811 may be implemented within a single processing device, but may also be distributed across multiple processing devices, sub-systems, or specialized circuitry, that cooperate in executing program instructions and in performing the operations discussed herein. Examples of processor 811 include general purpose central processing units, system-on-a-chip devices, application specific processors, and logic devices, as well as any other type of processing device, combinations, or variations thereof.

Storage system 813 may comprise any computer readable storage media readable by processor 811 and capable of storing software 820. Storage system 813 may include volatile and nonvolatile, removable and non-removable media implemented in any method or technology for storage of information, such as computer readable instructions, data structures, program modules, or other data. Examples of storage media include random access memory (RAM), read only memory (ROM), semiconductor storage media, magnetic storage media, optical storage media, flash storage media, virtual memory and non-virtual memory, or any other suitable storage media. In no case is the computer readable storage media a propagated signal. In addition to computer readable storage media, in some implementations storage system 813 may also include computer readable communication media over which at least some of software 820 may be communicated internally or externally. Storage system 813 may be implemented as a single storage device but may also be implemented across multiple storage devices or sub-systems co-located or distributed relative to each other. Storage system 813 may comprise additional elements, such as a controller, capable of communicating with processor 811 or possibly other systems.

Communication interface system 814 may include communication connections and devices that allow for communication with other computing systems (not shown) over communication networks (not shown). Communication interface system 814 can also include elements configured to communicate with controllers, power controllers, sensors, or other elements that provide indications of measurements of magnetic field properties. Examples of connections and devices that together allow for inter-system communication may include discrete links, network interface cards, antennas, power amplifiers, RF circuitry, transceivers, and other communication circuitry. The connections and devices may communicate over communication media to exchange packetized communications with other computing systems or networks of systems, such as metal, glass, air, or any other suitable communication media. Communication interface system 814 may include user interface elements, such as programming registers, status registers, control registers, APIs, or other user-facing preference elements. In some implementations, the user interface elements permit the user to specify the charge rate preference from a set of preferences, provide voice input to select a preference from a set of preferences, or provide input in some other manner to select the preference.

Communication interface system 814 can provide communications between computing system 810 and other computing systems (not shown), which may occur over a communication network or networks and in accordance with various communication protocols, combinations of protocols, or variations thereof. Communication interfaces might also include interfaces for communicating internally or externally to computing system 810 and comprise system management bus (SMB) interfaces, inter-integrated circuit (I2C) interfaces, or other similar interfaces. Further examples include intranets, internets, the Internet, local area networks, wide area networks, wireless networks, wired networks, virtual networks, software defined networks, data center buses, computing backplanes, or any other type of network, combination of network, or variation thereof. The aforementioned communication networks and protocols are well known and need not be discussed at length here. However, some communication protocols that may be used include, but are not limited to, the Internet protocol (IP, IPv4, IPv6, etc.), the transmission control protocol (TCP), and the user datagram protocol (UDP), as well as any other suitable communication protocol, variation, or combination thereof.

Software 820 may be implemented in program instructions and among other functions may, when executed by processor 811, direct processor 811 to operate as described with respect to the various operational scenarios, sequences, and processes illustrated herein. For example, software 820 may include program instructions for enhanced monitoring of connector coupling quality between a connector and a computing system, among other operations. In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. Software 820 may include additional processes, programs, or components, such as operating system software or other application software, in addition to that of coupling monitor system 821. Software 820 may also comprise software or some other form of machine-readable processing instructions executable by processor 811.

In general, software 820 may, when loaded into processor 811 and executed, transform a suitable apparatus, system, or device (of which computing system 810 is representative) overall from a general-purpose computing system into a special-purpose computing system customized to facilitate enhanced battery charging management of computing system 810. Indeed, encoding software 820 on storage system 813 may transform the physical structure of storage system 813. The specific transformation of the physical structure may depend on various factors in different implementations of this description. Examples of such factors may include, but are not limited to, the technology used to implement the storage media of storage system 813 and whether the computer-storage media are characterized as primary or secondary storage, as well as other factors. For example, if the computer readable storage media are implemented as semiconductor-based memory, software 820 may transform the physical state of the semiconductor memory when the program instructions are encoded therein, such as by transforming the state of transistors, capacitors, or other discrete circuit elements constituting the semiconductor memory. A similar transformation may occur with respect to magnetic or optical media. Other transformations of physical media are possible without departing from the scope of the present description, with the foregoing examples provided only to facilitate the present discussion.

Coupling monitor system 821 can include one or more software elements, such as an operating system, devices drivers, and one or more applications. These elements can describe various portions of computing system 810 with which power controllers, charging circuitry, coupling property sensor elements, power supply status elements, battery status elements, or other elements interact. For example, an operating system can provide a software platform on which coupling monitor system 821 is executed and allows for enhanced monitoring of connector coupling quality operations of computing system 810.

In one example, coupling quality detector 822, when executed by processor 811, directs computing system 810 to obtain indications of magnetic and/or electrical coupling properties of a connection between a connector of a power supply and a receptacle of computing system 810. Coupling quality detector 822, when executed by processor 811, may further direct computing system 810 to determine a coupling quality of the connection based on at least the indications of the coupling properties. Computing system 810 may determine the coupling quality of the connection using one or more of inputs 831, such as the magnetic field strength, the magnetic field orientation, the magnet orientation relative to a sensor, and a sensor position relative to the magnet and other elements of computing system 810, among other inputs described herein.

Based on the coupling quality of the connection falling below a threshold quality level, coupling state indicator 823, when executed by processor 811, directs computing system 810 to provide an indication of the coupling quality to a user interface of computing system 810. The indication presented on the user interface may include a pop-up window notification, a light indicator on a display screen or some peripheral of computing system 810, a sound indication played through a speaker of computing system 810, or the like. The indication may include one or more of outputs 832, such as magnetic coupling quality and a coupling state notification as described above, among other outputs described herein.

Certain inventive aspects may be appreciated from the foregoing disclosure, of which the following are various examples.

Example 1: A method, comprising obtaining indications of magnetic coupling properties of a connector with respect to a device, determining a coupling quality of a connection between the connector and the device based on at least on the indications of the magnetic coupling properties, and providing an indication based at least on the coupling quality of the connection falling below a threshold quality level.

Example 2: The method of example 1, wherein the indications of the magnetic coupling properties comprise at least one among a strength of a magnetic field or a relative orientation of the magnetic field between the connector and the device.

Example 3: The method of examples 1-2, wherein the coupling quality comprises at least one among: a first coupling quality, wherein the strength of the magnetic field satisfies a target coupling distance and the orientation of the magnetic field satisfies a target relative orientation, a second coupling quality, wherein the strength of the magnetic field satisfies the target coupling distance and the orientation of the magnetic field does not satisfy the target relative orientation, a third coupling quality, wherein the strength of the magnetic field does not satisfy the target coupling distance and the orientation of the magnetic field satisfies the target relative orientation, or a fourth coupling quality, wherein the strength of the magnetic field does not satisfy the target coupling distance and the orientation of the magnetic field does not satisfy the target relative orientation.

Example 4: The method of examples 1-3, wherein providing the indication comprises presenting a notification through a user interface of the device.

Example 5: The method of examples 1-4, wherein the notification comprises at least one among a status indication corresponding to the coupling quality or an instruction corresponding to user action to improve the coupling quality.

Example 6: The method of examples 1-5, comprising obtaining indications of electrical connection properties of the connector with respect to the device, wherein determining the coupling quality of the connection between the connector and the device is further based on the indications of the electrical connection properties.

Example 7: The method of examples 1-6, wherein the connector conforms to a Universal Serial Bus Type-C(USB-C) connection standard.

Example 8: The method of examples 1-7, wherein a physical linkage between the connector and the device is achieved by at least one among a magnetically-formed coupling connection, a friction-formed coupling connection, or an interlocking coupling connection.

Example 9: An apparatus, comprising sensing circuitry configured to measure magnetic coupling properties of a connector with respect to a device, processing circuitry coupled to the sensing circuitry and configured to obtain indications of the magnetic coupling properties measured by the magnetic sensing circuitry, determine a coupling quality of a connection between the connector and the device based at least on the indications of the magnetic coupling properties, and provide an indication based at least on the coupling quality of the connection falling below a threshold quality level.

Example 10: The apparatus of example 9, wherein the indications of the magnetic coupling properties comprise at least one among a strength of a magnetic field or a relative orientation of the magnetic field between the connector and the device.

Example 11: The apparatus of examples 9-10, wherein the coupling quality comprises at least one among: a first coupling quality, wherein the strength of the magnetic field satisfies a target coupling distance and the orientation of the magnetic field satisfies a target relative orientation, a second coupling quality, wherein the strength of the magnetic field satisfies the target coupling distance and the orientation of the magnetic field does not satisfy the target relative orientation, a third coupling quality, wherein the strength of the magnetic field does not satisfy the target coupling distance and the orientation of the magnetic field satisfies the target relative orientation, or a fourth coupling quality, wherein the strength of the magnetic field does not satisfy the target coupling distance and the orientation of the magnetic field does not satisfy the target relative orientation.

Example 12: The apparatus of examples 9-11, wherein to provide the indication, the processing circuitry is configured to present a notification through a user interface of the device.

Example 13: The apparatus of examples 9-12, wherein the notification comprises at least one among a status indication corresponding to the coupling quality or an instruction corresponding to user action to improve the coupling quality.

Example 14: The apparatus of examples 9-13, comprising obtaining indications of electrical coupling properties of the connector with respect to the device, wherein the processing circuitry is configured to determine the coupling quality of the connection between the connector and the device further based on the indications of the electrical coupling properties.

Example 15: The apparatus of examples 9-14, wherein the conforms to a Universal Serial Bus Type-C(USB-C) connection standard.

Example 16: The apparatus of examples 9-15, wherein the sensing circuitry comprises one or more Hall sensors.

Example 17: An apparatus, comprising a processing system operatively coupled with one or more computer readable storage media, and program instructions stored on the one or more computer readable storage media that, based on being read and executed by the processing system, direct the processing system to at least: obtain indications of magnetic coupling properties of a connector with respect to a device, determine a coupling quality of a connection between the connector and the device based at least on the indications of the magnetic coupling properties, and provide an indication based at least on the coupling quality of the connection falling below a threshold quality level.

Example 18: The apparatus of example 17, wherein the indications of the magnetic coupling properties comprise at least one among a strength of a magnetic field or a relative orientation of the magnetic field between the connector and the device.

Example 19: The apparatus of examples 17-18, wherein the coupling quality comprises at least one among: a first coupling quality, wherein the strength of the magnetic field satisfies a target coupling distance and the orientation of the magnetic field satisfies a target relative orientation, a second coupling quality, wherein the strength of the magnetic field satisfies the target coupling distance and the orientation of the magnetic field does not satisfy the target relative orientation, a third coupling quality, wherein the strength of the magnetic field does not satisfy the target coupling distance and the orientation of the magnetic field satisfies the target relative orientation, or a fourth coupling quality, wherein the strength of the magnetic field does not satisfy the target coupling distance and the orientation of the magnetic field does not satisfy the target relative orientation.

Example 20: The apparatus of examples 17-19, wherein to provide the indication, the program instructions direct the processing system to present a notification through a user interface of the device, wherein the notification comprises at least one among a status indication corresponding to the coupling quality or an instruction corresponding to user action to improve the coupling quality.

The functional block diagrams, operational scenarios and sequences, and flow diagrams provided in the Figures are representative of exemplary systems, environments, and methodologies for performing novel aspects of the disclosure. The descriptions and figures included herein depict specific implementations to teach those skilled in the art how to make and use the best option. For the purpose of teaching inventive principles, some conventional aspects have been simplified or omitted. Those skilled in the art will appreciate variations from these implementations that fall within the scope of the disclosed examples. Those skilled in the art will also appreciate that the features described above can be combined in various ways to form multiple implementations. As a result, the invention is not limited to the specific implementations described above, but only by the claims and their equivalents.

The various materials and manufacturing processes discussed herein are employed according to the descriptions above. However, it should be understood that the disclosures and enhancements herein are not limited to these materials and manufacturing processes and can be applicable across a range of suitable materials and manufacturing processes. Thus, the descriptions and figures included herein depict specific implementations to teach those skilled in the art how to make and use the best options. For the purpose of teaching inventive principles, some conventional aspects have been simplified or omitted. Those skilled in the art will appreciate variations from these implementations that fall within the scope of this disclosure. Those skilled in the art will also appreciate that the features described above can be combined in various ways to form multiple implementations.

What is claimed is:

1. A method, comprising:
obtaining indications of magnetic coupling properties of a connector with respect to a device;
determining a coupling quality of a connection between the connector and the device based on at least on the indications of the magnetic coupling properties; and
providing an indication based at least on the coupling quality of the connection falling below a threshold quality level.

2. The method of claim 1, wherein the indications of the magnetic coupling properties comprise at least one among a strength of a magnetic field or a relative orientation of the magnetic field between the connector and the device.

3. The method of claim 2, wherein the coupling quality comprises at least one among:
a first coupling quality, wherein the strength of the magnetic field satisfies a target coupling distance and the orientation of the magnetic field satisfies a target relative orientation;
a second coupling quality, wherein the strength of the magnetic field satisfies the target coupling distance and the orientation of the magnetic field does not satisfy the target relative orientation;
a third coupling quality, wherein the strength of the magnetic field does not satisfy the target coupling distance and the orientation of the magnetic field satisfies the target relative orientation; or
a fourth coupling quality, wherein the strength of the magnetic field does not satisfy the target coupling distance and the orientation of the magnetic field does not satisfy the target relative orientation.

4. The method of claim 1, wherein providing the indication comprises presenting a notification through a user interface of the device.

5. The method of claim 4, wherein the notification comprises at least one among a status indication corresponding to the coupling quality or an instruction corresponding to user action to improve the coupling quality.

6. The method of claim 1, comprising obtaining indications of electrical connection properties of the connector with respect to the device, wherein determining the coupling quality of the connection between the connector and the device is further based on the indications of the electrical connection properties.

7. The method of claim 1, wherein the connector conforms to a Universal Serial Bus Type-C(USB-C) connection standard.

8. The method of claim 1, wherein a physical linkage between the connector and the device is achieved by at least one among a magnetically-formed coupling connection, a friction-formed coupling connection, or an interlocking coupling connection.

9. An apparatus, comprising:
sensing circuitry configured to measure magnetic coupling properties of a connector with respect to a device; and
processing circuitry coupled to the magnetic sensing circuitry and configured to:
obtain indications of the magnetic coupling properties measured by the sensing circuitry;
determine a coupling quality of a connection between the connector and the device based at least on the indications of the magnetic coupling properties; and
provide an indication based at least on the coupling quality of the connection falling below a threshold quality level.

10. The apparatus of claim 9, wherein the indications of the magnetic coupling properties comprise at least one among a strength of a magnetic field or a relative orientation of the magnetic field between the connector and the device.

11. The apparatus of claim 10, wherein the coupling quality comprises at least one among:
a first coupling quality, wherein the strength of the magnetic field satisfies a target coupling distance and the orientation of the magnetic field satisfies a target relative orientation;
a second coupling quality, wherein the strength of the magnetic field satisfies the target coupling distance and the orientation of the magnetic field does not satisfy the target relative orientation;
a third coupling quality, wherein the strength of the magnetic field does not satisfy the target coupling distance and the orientation of the magnetic field satisfies the target relative orientation; or
a fourth coupling quality, wherein the strength of the magnetic field does not satisfy the target coupling distance and the orientation of the magnetic field does not satisfy the target relative orientation.

12. The apparatus of claim 9, wherein to provide the indication, the processing circuitry is configured to present a notification through a user interface of the device.

13. The apparatus of claim 12, wherein the notification comprises at least one among a status indication corresponding to the coupling quality or an instruction corresponding to user action to improve the coupling quality.

14. The apparatus of claim 9, comprising obtaining indications of electrical coupling properties of the connector with respect to the device, wherein the processing circuitry is configured to determine the coupling quality of the connection between the connector and the device further based on the indications of the electrical coupling properties.

15. The apparatus of claim 9, wherein the conforms to a Universal Serial Bus Type-C (USB-C) connection standard.

16. The apparatus of claim 9, wherein the sensing circuitry comprises one or more Hall sensors.

17. An apparatus, comprising:
a processing system operatively coupled with one or more computer readable storage media; and
program instructions stored on the one or more computer readable storage media that, based on being read and executed by the processing system, direct the processing system to at least:
obtain indications of magnetic coupling properties of a connector with respect to a device;
determine a coupling quality of a connection between the connector and the device based at least on the indications of the magnetic coupling properties; and
provide an indication based at least on the coupling quality of the connection falling below a threshold quality level.

18. The apparatus of claim 17, wherein the indications of the magnetic coupling properties comprise at least one among a strength of a magnetic field or a relative orientation of the magnetic field between the connector and the device.

19. The apparatus of claim 18, wherein the quality state comprises at least one among:
a first coupling quality, wherein the strength of the magnetic field satisfies a target coupling distance and the orientation of the magnetic field satisfies a target relative orientation;
a second coupling quality, wherein the strength of the magnetic field satisfies the target coupling distance and the orientation of the magnetic field does not satisfy the target relative orientation;
a third coupling quality, wherein the strength of the magnetic field does not satisfy the target coupling distance and the orientation of the magnetic field satisfies the target relative orientation; or
a fourth coupling quality, wherein the strength of the magnetic field does not satisfy the target coupling distance and the orientation of the magnetic field does not satisfy the target relative orientation.

20. The method of claim 18, wherein to provide the indication, the program instructions direct the processing system to present a notification through a user interface of the device, wherein the notification comprises at least one among a status indication corresponding to the coupling quality or an instruction corresponding to user action to improve the coupling quality.
